(19) United States
(12) Patent Application Publication
(10) Pub. No.: US 2006/0186471 A1
(43) Pub. Date: Aug. 24, 2006

(54) Manufacturing method for semiconductor device

(75) Inventor: Hirotaka Komatsubara, Tokyo (JP)

Correspondence Address: Rabin & Berdo, P.C.;Suite 500, 1101 14th Street, N.W., Washington, DC, 20005, US

(73) Assignee: Oki Electric Industry Co., Ltd., Tokyo (JP)

(21) Appl. No.: 11/411,885

(22) Filed: Apr. 27, 2006

Related U.S. Application Data
(62) Division of application No. 10/962,595, filed on Oct. 13, 2004, now abandoned.

(30) Foreign Application Priority Data
Mar. 24, 2004 (JP) 2004-86909

(51) Int. Cl. H01L 29/76

(52) U.S. Cl. 257/344

(57) ABSTRACT

A semiconductor device with simple device structure enables reduction in the number of manufacturing steps and the manufacturing cost. A gate insulation film and a gate electrode are formed in a certain area on a semiconductor substrate. A semiconductor substrate non-removed section is formed under the gate insulation film, and semiconductor substrate removed regions are formed around the non-removed section by etching. After an LDD source region and an LDD drain region which have low impurity concentration are formed in the removed regions, sidewalls are formed on the side faces of the gate electrode, the gate insulation film, and the non-removed section. After that, a source region and a drain region with high impurity concentration are formed in the removed regions around the sidewalls.

### BACKGROUND OF THE INVENTION

1. Field of the Invention

The present invention relates to a semiconductor device such as a MOSFET (MOS field-effect transistor) in which a source/drain region has an LDD (lightly doped drain) structure, and a manufacturing method thereof.

2. Description of the Related Art

Conventionally, for example, Japanese Patent Kokai No. 10-247693 (patent document 1) discloses a technology relating to a semiconductor device (for example, a nonvolatile semiconductor memory) with the LDD structure.

FIGS. 1A to 1F are diagrams of manufacturing process which together show an example of a method for manufacturing a general MOSFET having the LDD structure.

Referring to FIG. 1A, in the MOSFET, an oxide film is deposited on the surface of a semiconductor substrate 1 made of a silicon (Si) substrate to form a device isolation region, and then a gate insulation film 2 being a gate oxide film is deposited thereon. As shown in FIG. 1B, an electrode material is deposited on the gate insulation film 2, and the electrode material and the gate insulation film 2 are selectively removed by lithography technology and etching technique to form a gate electrode 3. In FIG. 1C, impurity ions are implanted in the semiconductor substrate 1 by the use of the gate electrode 3 as a mask, so that an LDD source region 4S becoming a part of a source and an LDD drain region 4D becoming a part of a drain (impurity concentration of 1×10¹⁸ to 1×10²⁰ cm⁻³) are formed.

Then, referring to FIG. 1D, an insulation film made of an oxide film is deposited on the whole surface of the semiconductor substrate by a CVD (chemical vapor deposition) method. Then, the insulation film is maintained only on the sidewalls of the gate electrode 3 by the etching technique to form sidewalls 5. In FIG. 1E, impurity ions are implanted in the semiconductor substrate 1 by the use of the gate electrode 3 and the sidewalls 5 as masks, so that a source region 6S and a drain region 6D (impurity concentration of 1×10²⁰ to 1×10²² cm⁻³) are formed. Subsequently, in FIG. 1F, heat treatment (activation anneal) is carried out to activate the implanted ions and recover the crystallization of the semiconductor substrate 1 to complete the MOSFET.

FIG. 2 shows an energy band diagram which explains the tunnel conduction described below, which is discussed in the patent document 1.

In a semiconductor device with the LDD structure as shown in FIGS. 1A to 1F, electron-hole pairs are generated due to a drain band-to-band tunneling phenomenon (that is, a phenomenon in which band-to-band tunneling current occurs between the gate electrode and the drain region entering under the gate electrode) as described in the patent document 1. Such a generation of electron-hole pairs is the field emission of electrons from a valence band to a conduction band in a region (a diagonally shaded region 7 in FIG. 2) in which an energy state of the valence band becomes equal to that of the conduction band due to variation in potential. Thus, the generation of electron-hole pairs greatly depends on the potential distribution.

Specifically, when the drain region 6D has a relatively low impurity concentration (approximately 1×10¹⁸ cm⁻³ or less), a potential gradient in the region 7, in which the energy state of the valence band becomes equal to that of the conduction band, is gentle, so that the speed of the generation of electron-hole pairs due to the band-to-band tunneling phenomenon is slow. When the drain region 6D has a relatively high impurity concentration (approximately 1×10¹⁹ cm⁻³ or more), on the other hand, potential does not vary to such an extent that the energy state of the valence band becomes equal to that of the conduction band, and hence the band-to-band tunneling phenomenon does not occur. When the drain region 6D has an impurity concentration inbetween the low and high concentrations mentioned above (approximately 1×10¹⁸ cm⁻³ to 1×10¹⁹ cm⁻³), the potential gradient in the region 7, in which the energy state of the valence band becomes equal to that of the conduction band, is steep, so that the speed of the generation of electron-hole pairs due to the band-to-band tunneling phenomenon becomes extremely fast. Therefore, to adequately reduce consumption current due to the band-to-band tunneling phenomenon, it is necessary to form the drain region 6D with the relatively low impurity concentration (approximately 1×10¹⁸ cm⁻³ or less) or with the high impurity concentration (approximately 1×10¹⁹ cm⁻³ or more). To realize high speed operation, on the other hand, it is necessary to reduce the resistance of the drain region 6D. From that viewpoint, the higher the impurity concentration of the drain region 6D, the more preferable it is.

According to conditions described above, the MOSFET is generally manufactured in such a manner that a region with the adequately high impurity concentration is formed in the drain region 6D by high-dose ion implantation or the like.

Since the drain region 6D formed by the high-dose ion implantation or the like in such a manner, however, has a concentration distribution directly under the gate insulation film 2, a region with the extremely high speed of the occurrence of the electron-hole pairs due to the band-to-band tunneling phenomenon is inevitably formed. Thus, there is a problem that large leakage current occurs. In a case that the MOSFET has an N-channel, of the electron-hole pairs generated by the foregoing band-to-band tunneling phenomenon, holes which have obtained energy from an electric field directed from the drain region 6D to the semiconductor substrate 1, are introduced in the gate insulation film 2. It is known that this phenomenon adversely affects the long-term reliability of the gate insulation film 2, and degrades various characteristics of a memory cell such as writing speed.

As a measure to prevent such degradation, there are cases that the drain region 6D is further covered by a diffusion layer with low impurity concentration to weaken the strength of the electric field. In such cases, however, substantial decrease in channel length makes the manufacture of the MOSFET difficult.

As one of methods for solving the problems described above, as disclosed in the patent document 1, a structure is proposed in which pileup diffusion layers are piled on each of the source region 6S and the drain region 6D.

In the conventional structure according to the patent document 1 in which a source and a drain are piled up, however, it is necessary to add a pileup process. Therefore, there are problems that the structure of the semiconductor device becomes complex, and the number of manufacturing processes and the cost increase.

### SUMMARY OF THE INVENTION

To solve the foregoing conventional problems, an object of the present invention is to provide a semiconductor device with simple structure, and a manufacturing method thereof which can reduce the number of manufacturing processes and the cost.

To achieve the foregoing object, a semiconductor device according to the present invention comprises a gate insulation film, a gate electrode, a semiconductor substrate non-removed section, semiconductor substrate removed regions, an LDD source region, an LDD drain region, sidewalls, a source region, and a drain region. The gate insulation film is formed in a certain area on a semiconductor substrate, and the gate electrode is formed on the gate insulation film. The semiconductor substrate non-removed section is formed under the gate insulation film, and the semiconductor substrate removed regions are formed around the semiconductor substrate non-removed section by etching the surface of the semiconductor substrate exclusive of a region of the gate electrode to a certain depth. The LDD source region and the LDD drain region, composed of first impurity ion diffusion regions, are formed in the semiconductor substrate removed regions so as to be adjacent to the gate electrode region. The sidewalls made of an insulation film are formed on the side faces of the gate electrode, the gate insulation film, and the semiconductor substrate non-removed section. The source region and the drain region are composed of second impurity ion diffusion regions. The impurity concentration of the second impurity ion is higher than that of the first impurity ion. The source region and the drain region are formed in the semiconductor substrate removed regions so as to be adjacent to regions where the sidewalls are formed.

According to the present invention, the distance between the gate insulation film and the LDD source region and between the gate insulation film and the LDD drain region is large because of the existence of the semiconductor substrate non-removed section. Thus, for example, the value of drain current flowing between the source and the drain at a gate voltage of approximately 0 V becomes lower than that of a conventional MOSFET, so that it is possible to lower the drain current during a standby period. Therefore, as compared with the conventional MOSFET, it is possible to reduce off leakage current without changing the value of drive current. Furthermore, the LDD source region and the source region, and the LDD drain region and the drain region are formed in the semiconductor substrate removed regions, in which the semiconductor substrate is removed. Therefore, it is possible to simplify the structure of the device, and hence reduction in the number of manufacturing steps and manufacturing costs.

### BRIEF DESCRIPTION OF THE DRAWINGS

FIGS. 1A to 1F are manufacturing process drawings which show an example of a method for manufacturing a MOSFET having the conventional LDD structure;

FIG. 2 is a diagram showing an energy band for explaining the tunnel conduction;

FIGS. 3A to 3H are drawings of manufacturing process which show an example of a method for manufacturing a MOSFET with the LDD structure according to a first embodiment of the present invention;

FIG. 4 is a graph showing the relationship between the gate voltage and the drain current in the MOSFET according to the first embodiment; and

FIG. 5 is a diagram showing energy bands in the surfaces of a conventional semiconductor substrate and a semiconductor substrate according to the first embodiment of the invention.

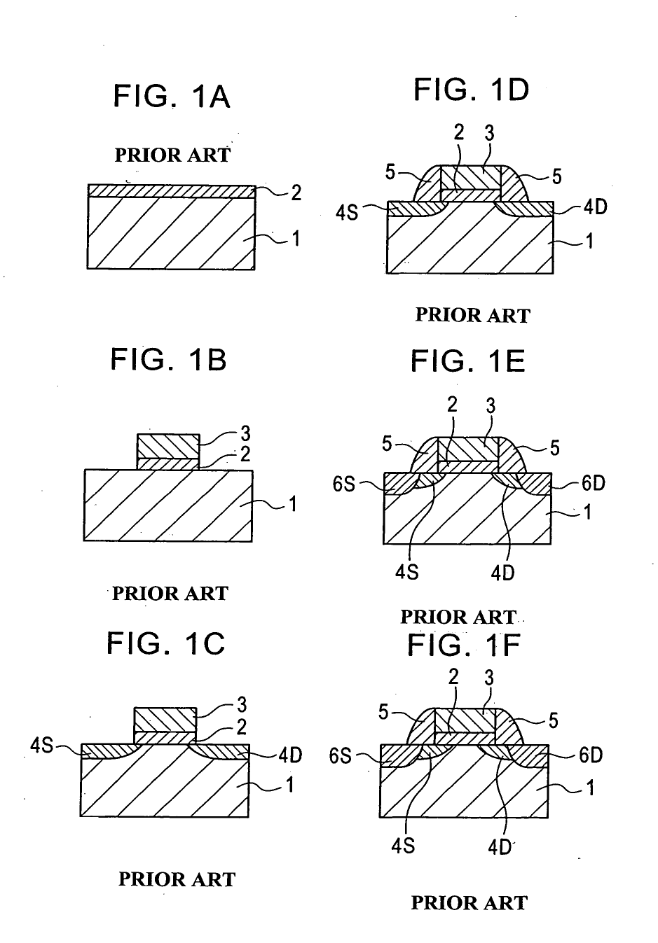

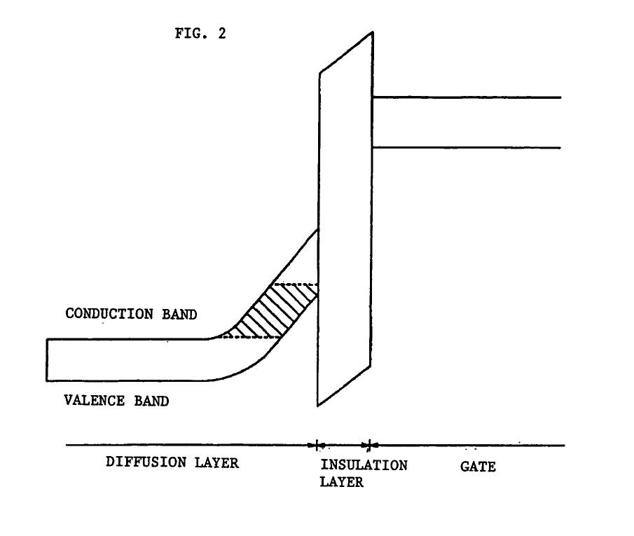

### DETAILED DESCRIPTION OF THE INVENTION

To manufacture a semiconductor device according to the present invention, a gate insulation film is first formed in a certain area on a semiconductor substrate, and a gate electrode is formed on the gate insulation film. The surface of the semiconductor substrate is etched to a certain depth by the use of the gate electrode as a mask, to form a semiconductor substrate non-removed section under the gate insulation film. Semiconductor substrate removed regions are formed around the semiconductor substrate non-removed section.

Then, first impurity ions are implanted in the semiconductor substrate removed regions by the use of the gate electrode as a mask to form an LDD source region and an LDD drain region. Sidewalls made of an insulation film are formed on the side faces of the gate electrode, the gate insulation film, and the semiconductor substrate non-removed section. After that, second impurity ions having higher impurity concentration than the first impurity ions are implanted in the semiconductor substrate removed regions by the use of the gate electrode and the sidewalls as masks, to form a source region and a drain region.

[Structure]

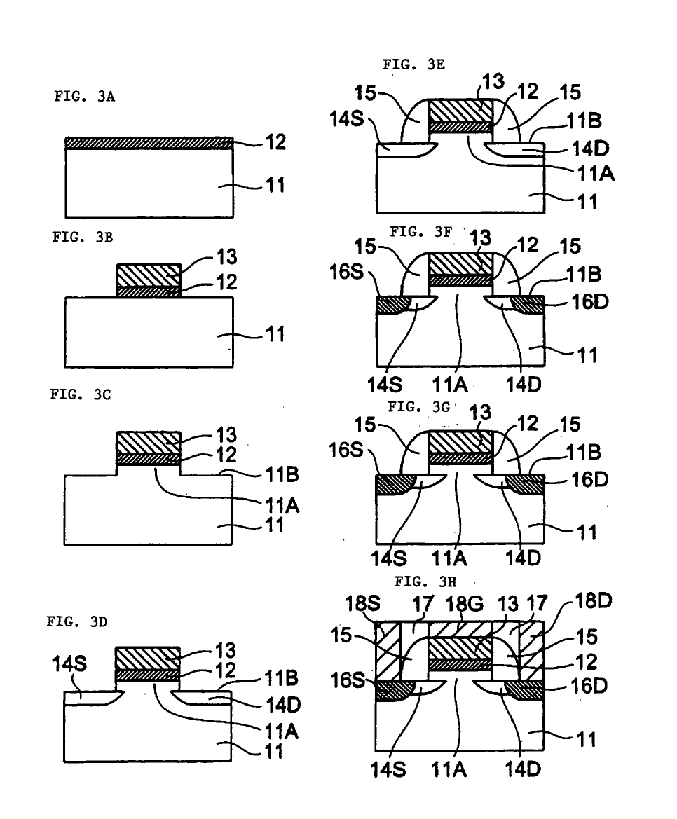

FIGS. 3A to 3H are drawings of manufacturing process which show an example of a method for manufacturing a MOSFET with the LDD structure according to a first embodiment of the present invention, and FIG. 3H is a schematic sectional view of the MOSFET after an electrodes forming process.

As shown in FIG. 3G, the MOSFET according to the first embodiment has a semiconductor substrate 11 made of an Si substrate or the like, and a semiconductor substrate non-removed section (hereinafter simply called “non-removed section”) 11A is formed in a certain area on the semiconductor substrate 11. Semiconductor substrate removed regions (hereinafter simply called “removed regions”) 11B with a certain depth are formed in the periphery of the non-removed section 11A by etching. A gate insulation film 12 such as a gate oxide film is formed on the non-removed section 11A, and a gate electrode 13 is formed on the gate insulation film 12.

In the removed regions 11B around the non-removed section 11A in the semiconductor substrate 11, an LDD source region 14S and an LDD drain region 14D which have low impurity concentrations are formed by implanting first impurity ions. A part of the LDD source region 14S and a part of the LDD drain region 14D enter under the non-removed section 11A. Sidewalls 15 which are made of an insulation film such as an oxide film are formed on the side faces of the non-removed section 11A, the gate insulation film 12, and the gate electrode 13. In the removed regions 11B around the sidewalls 15, a source region 16S and a drain region 16D which have high impurity concentration are formed by implanting second impurity ions. The source region 16S and the drain region 16D are deeper than the LDD source region 14S and the LDD drain region 14D, and a part of the source region 16S and a part of the drain region 16D enter under the sidewalls 15.

An insulation film 17 such as an oxide film is formed in such a manner as to cover the whole surfaces of the gate electrode 13, the sidewalls 15, the source region 16S, and the drain region 16D. Certain portions of the insulation film 17 are opened, and metal electrode materials such as aluminum (Al) are embedded therein to form a source electrode 18S, a drain electrode 18D, and a gate electrode 18G which are made of metal. The metal source electrode 18S, the drain electrode 18D, and the gate electrode 18G are electrically connected to the source region 16S, the drain region 16D, and the gate electrode 13, respectively.

### EXAMPLE OF MANUFACTURING METHOD

Referring to FIGS. 3A to 3H, an example of a method for manufacturing the MOSFET with the LDD structure according to the first embodiment will be described.

First, in a gate insulation film deposit process shown in FIG. 3A, a not-illustrated oxide film is deposited on the surface of the semiconductor substrate 11 made of the Si substrate to form a device isolation region. After that, the gate insulation film 12 made of the gate oxide film is deposited thereon by wet oxidation at 850 degrees centigrade and thermal oxidation for approximately ten minutes.

In a gate electrode forming process shown in FIG. 3B, a poly-Si film being an electrode material is deposited by a CVD method to provide a thickness of approximately 150 nm to 250 nm. The whole surface of the poly-Si film is masked (covered) by a resist film, and a certain portion of the poly-Si film is removed by using photolithography technique and etching technique to form the gate electrode 13. The gate insulation film 12 is left under the gate electrode 13.

In a substrate etching process shown in FIG. 3C, the semiconductor substrate 11 is over-etched to the certain depth by the use of the gate electrode 13 as a mask, in order to form the removed regions 11B and leave the non-removed section 11A under the gate insulation film 12.

In an LDD ion implantation process shown in FIG. 3D, the first impurity ions such as arsenic are ion-implanted in the removed regions 11B at approximately 10 keV1E14(cm⁻²) by the use of the gate electrode 13 as a mask. Thus, the LDD source region 14S and the LDD drain region 14D (impurity concentration of 1×10¹⁸ to 1×10²⁰ cm⁻³) which become a part of the source and drain are formed. A part of the LDD source region 14S and a part of the LDD drain region 14D diffuse under the non-removed section 11A.

In a sidewall forming process shown in FIG. 3E, the insulation film for the sidewalls such as the oxide film is deposited by the CVD method to provide a thickness of approximately 150 nm to 250 nm. The whole surface of the insulation film is masked by a resist film, and the insulation film for the sidewalls is left only on the side faces of the gate electrode 13, the gate insulation film 12, and the non-removed section 11A by the photolithography technique and the etching technique to form the sidewalls 15.

In a source/drain ion implantation process shown in FIG. 3F, the second impurity ions such as arsenic are ion-implanted in the removed region 11B at approximately 70 keV5E15(cm⁻²) by the use of the gate electrode 13 and the sidewalls 15 as masks, in order to form the source region 16S and the drain region 16D (impurity concentration of 1×10²⁰ to 1×10²² cm⁻³). The source region 16S and the drain region 16D diffuse more deeply than the LDD source region 14S and the LDD drain region 14D, and a part of the source region 16S and a part of the drain region 16D diffuse into the removed regions 11B under the sidewalls 15.

In an activate heat treatment process shown in FIG. 3G, heat treatment (activation anneal) is carried out at approximately 1000 degrees centigrade for approximately ten seconds in an atmosphere of nitrogen (N) or the like, to activate the implanted ions and recover the crystallization of the semiconductor substrate 11. Accordingly, the source region 16S and the drain region 16D become deeper by being activated.

After that, in an electrodes forming process shown in FIG. 3H, the insulation film 17 such as the oxide film is deposited by the CVD method. Then, the insulation film 17 is masked by a resist film, and electrode formation planning portions of the insulation film 17 are opened by the photolithography technique and the etching technique. By embedding the metal electrode materials such as Al in the open portions, the source electrode 18S, the drain electrode 18D, and the gate electrode 18G are formed. Therefore, the metal source electrode 18S, the drain electrode 18D, and the gate electrode 18G are electrically connected to the source region 16S, the drain region 16D, and the gate electrode 13, respectively. The manufacturing process of the MOSFET with the use of the LDD structure is completed.

[Operations and Effects]

Operations and effects which are obtained in the first embodimentas will be described in the following paragraphs (1) to (4).

(1) The surface of the semiconductor substrate 11 is removed by etching in the substrate etching process shown in FIG. 3C before the LDD-ion implantation, to form the non-removed section 11A and the removed regions 11B. Therefore, removing the semiconductor substrate 11 can change the distribution of the impurity in an impurity diffusion layer under the gate insulation film 12.

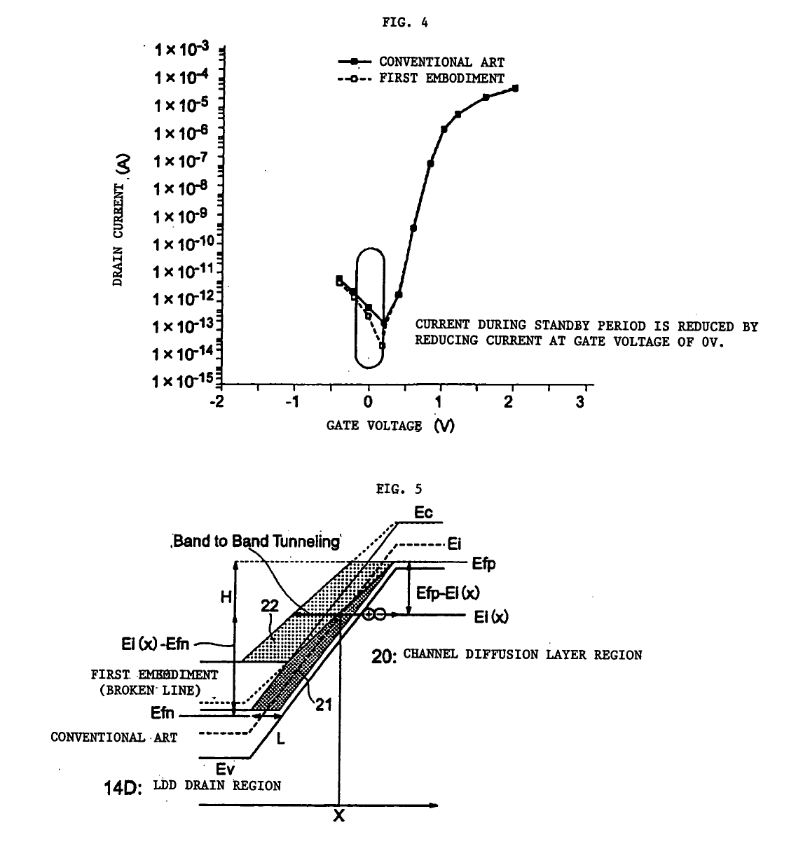

(2) FIG. 4 is a graph showing the relation between the gate voltage and the drain current in the MOSFET according to the first embodiment.

In FIG. 4, solid lines indicate characteristic curves of a conventional MOSFET, and broken lines indicate characteristic curves of the MOSFET according to the first embodiment. In the first embodiment, the distance between the gate insulation film 12 and the LDD source region 14S and between the gate insulation film 12 and the LDD drain region 14D is large because of the existence of the non-removed section 11A. Thus, for example, the value of drain current flowing between the source and the drain at a gate voltage of approximately 0 V becomes lower, as compared with that of the conventional MOSFET, so that it is possible to lower the drain current during standby. Therefore, as compared with the conventional MOSFET, it is possible to reduce off-leakage current without changing the value of drive current. A reason for this will be described in the following (3).

(3) FIG. 5 shows energy bands in the surfaces of a conventional semiconductor substrate 1 and a semiconductor substrate 11 according to the first embodiment.

In FIG. 5, a channel diffusion layer region 20 corresponds to a region between the LDD source region 14S and source region 16S and the LDD drain region 14D and drain region 16D in FIG. 3H. A symbol Ev represents the upper limit of a valence band, and Ec represents the lower limit of a conduction band. The area between Ec and Ev is a forbidden band (an area in which no electron and hole can exist). Ei is a Fermi level (the center value between Ec and Ev), and Ei(x) is energy of an electron pair which becomes a leakage current. The conventional MOSFET has a band height between Ev and Efn drawn by solid lines, but the MOSFET of the first embodiment has a band height between Efn and Ec drawn by broken lines.

The leakage current flows when electrons in the channel diffusion layer region 20 flow across the energy band (a frame 21 and a frame 22). The off-leakage current is the leakage current when the MOSFET is in an OFF state and no channel exists between the source and the drain. When the band height H is low and band width L is wide, an amount of electrons which jump the band is reduced, so that the leakage current does not flow.

When the gate voltage is low and the impurity concentration of the LDD drain region 14D and the channel diffusion layer region 20 is high, the electron may jump the energy band. This electron flows as current. However, when the distance between the gate insulation film 12 and the LDD source region 14S and the distance between the gate insulation film 12 and the LDD drain region 14D are made large by the provision of the non-removed section 11A, as in the case of the first embodiment, the impurity concentration becomes low as compared with the conventional MOSFET, so that the electron hardly jumps the energy band. Therefore, it is possible to restrain the leakage current (off leakage current).

(4) The LDD source region 14S and the source region 16S, and the LDD drain region 14D and the drain region 16D are formed in the removed regions 11B, in which the semiconductor substrate 11 is removed. Therefore, the structure of the device is simplified, and hence it is possible to reduce the number of manufacturing processes and the cost.

The present invention is not limited to the foregoing first embodiment, and various modifications are possible. For example, the following paragraphs (a) and (b) describe a second embodiment as a modified example.

(a) The first embodiment describes the MOSFET using the LDD structure. A feature of the present invention, however, is structure having the non-removed section 11A under the gate. The present invention is applicable to various semiconductor devices such as another nonvolatile memory cell except for the MOSFET, as long as the semiconductor device has such structure.

(b) Manufacturing conditions such as materials, temperature and time in the manufacturing method shown in FIGS. 3A to 3H are just an example, and the manufacturing conditions can be variously modified in accordance with the semiconductor device to be manufactured.

This application is based on Japanese Patent Application No. 2004-086909 which is herein incorporated by reference.

1. (canceled)

2. A method for manufacturing a semiconductor device, comprising the steps of:
forming a gate insulation film in a certain area on a semiconductor substrate, and forming a gate electrode on the gate insulation film;
etching the surface of the semiconductor substrate to a certain depth by using the gate electrode as a mask to form a semiconductor substrate non-removed region under the gate insulation film, and form a semiconductor substrate removed region around the semiconductor substrate non-removed region;
implanting first impurity ions in the semiconductor substrate removed regions by using the gate electrode as a mask, to form an LDD source region and an LDD drain region;
forming sidewalls of an insulation film on side faces of the gate electrode, the gate insulation film, and the semiconductor substrate non-removed section after the step of implanting first impurity ions; and
implanting second impurity ions in the semiconductor substrate removed regions by using the gate electrode and the sidewalls as masks to form a further source region and a further drain region, wherein an impurity concentration of the second impurity ions is higher than an impurity concentration of the first impurity ions.

3. The method for manufacturing a semiconductor device according to claim 2, further comprising the step of:
carrying out heat treatment to activate the implanted ions and recover crystallization of the semiconductor substrate, after formation of the source region and the drain region.

4. The method of manufacturing a semiconductor device according to claim 2, wherein the impurity concentration of the first impurity ions is 1 H 10¹⁸ to 1 H 10²⁰ cm^{-3.}

5. The method of manufacturing a semiconductor device according to claim 2, wherein the impurity concentration of the second impurity ions is 1 H 10²⁰ to 1 H 10²² cm⁻³.

6. The method of manufacturing a semiconductor device according to claim 2, wherein the first impurity ions comprise arsenic.

7. The method of manufacturing a semiconductor device according to claim 2, wherein the second impurity ions comprise arsenic.

8. The method of manufacturing a semiconductor device according to claim 2, wherein the step of forming sidewalls of the insulation film comprises depositing an oxide film by CVD.

9. The method of manufacturing a semiconductor device according to claim 2, wherein the step of forming sidewalls of the insulation film comprises depositing a film having a thickness of between 150 nm and 250 nm.

10. A method for manufacturing a semiconductor device, comprising the steps of:
forming a gate electrode in a selected area on a semiconductor substrate;
implanting first impurity ions in the semiconductor substrate by using the gate electrode as a mask, to form a source region and a drain region;
forming sidewalls of an insulation film on side faces of the gate electrode after the step of implanting first impurity ions; and
implanting second impurity ions by using the gate electrode and the sidewalls as masks,
wherein the impurity concentration of the second impurity ions is higher than that of the first impurity ions.

11. The method for manufacturing a semiconductor device according to claim 10, further comprising the step of:
carrying out heat treatment to activate the implanted ions and recover crystallization of the semiconductor substrate, after formation of the source region and the drain region.

12. The method according to claim 8, further comprising the step of:
etching the surface of the semiconductor substrate to a certain depth by using the gate electrode as a mask to form a semiconductor substrate non-removed region under the gate insulation film, and form a semiconductor substrate removed region around the semiconductor substrate non-removed region.

13. The method of manufacturing a semiconductor device according to claim 10, wherein the impurity concentration of the first impurity ions is 1 H 10¹⁸ to 1 H 10²⁰ cm^{-3.}

14. The method of manufacturing a semiconductor device according to claim 10, wherein the impurity concentration of the second impurity ions is 1 H 10²⁰ to 1 H 10²² cm⁻³.

15. The method of manufacturing a semiconductor device according to claim 10, wherein the first impurity ions comprise arsenic.

16. The method of manufacturing a semiconductor device according to claim 10, wherein the second impurity ions comprise arsenic.

17. The method of manufacturing a semiconductor device according to claim 10, wherein the step of forming sidewalls of the insulation film comprises depositing an oxide film by CVD.

18. The method of manufacturing a semiconductor device according to claim 10, wherein the step of forming sidewalls of the insulation film comprises depositing a film having a thickness of between 150 nm and 250 nm.
